(19) United States
(12) Patent Application Publication
(10) Pub. No.: US 2015/0222241 A1
(43) Pub. Date: Aug. 6, 2015

(54) Circuit for Signal Transfer and Galvanic Isolation

(71) Applicant: Endress + Hauser Flowtec AG, Reinach (DE)

(72) Inventors: Matthias Brudermann, Moehlin (CH); Daniel Kollmer, Maulburg (DE); Christoph Werle, Liestal (CH)

(21) Appl. No.: 14/422,305

(22) PCT Filed: Jul. 26, 2013
(86) PCT No.: PCT/EP2013/065779

§ 371 Date: Feb. 18, 2015

(30) Foreign Application Priority Data
Aug. 24, 2012 (DE) 10 2012 107 818.1

(51) Int. Cl. H03H 7/00; H04B 5/00

(52) U.S. Cl. CPC H03H 7/004; H04B 5/0031

(57) ABSTRACT

A circuit for signal transfer and galvanic isolation between first and second digital signal processing units, wherein a first signal path is provided between the first and second signal processing units. The first signal path has a first section, which includes positive and negative signal lines and serves for transfer of a differential signal between the first and second signal processing units. At least one capacitor is provided in the positive signal line and at least one capacitor in the negative signal line. The capacitors serve for galvanic isolation between the first signal processing unit and the second signal processing unit, and the capacitors are embodied, in each case, according to the specifications of the ignition protection type, intrinsic safety.

The present invention relates to a circuit for signal transfer and galvanic isolation between first and second digital signal processing units. Furthermore, the invention relates to a field device of process automation technology as well as to a method for signal transfer and galvanic isolation between a first and a second signal processing unit.

Used today for signal transfer are, for example, differential signals, such as, for example, a so-called LVDS signal. LVDS stands for low voltage differential signaling. This type of differential data transfer occurs via positive and negative signal lines, wherein transmitted via the positive signal line is a positive signal and via the negative signal line a negative signal. The negative signal is, in such case, equal, however, of opposite polarity, to the positive signal. Such differential data transfer is documented, for example, in the data sheet AN-5048 of the firm, Fairchild Semiconductor.

Known from European patent EP 0811217 B1 is a circuit for electrical isolation of interfaces for differential signals. Capacitors are integrated in its positive and negative signal lines.

Besides galvanic isolation, of interest in explosion-endangered regions is the fulfillment of protective measures for avoiding explosions or for keeping the consequences of an explosion as small as possible. Besides primary explosion protection, in the case of which use of easily flammable materials is avoided, secondary explosion protection concerns avoiding potential ignition sources. Furthermore, there is so-called structural explosion protection, in the case of which, for example, explosion resistant components are used. Known, for example, is the ignition protection type, intrinsic safety, which applies to electrical, respectively electronic, equipment. Such ignition protection type, known also as Ex I, is defined in EN60079-11.

Further known from US-patent application US 20100054345 A1 is a galvanically isolated interface for differential signal transfer.

Additionally known from process automation are field devices for monitoring and/or control of processes in industrial plants. These field devices use so-called fieldbus protocols, for example, for measured value transfer. One of these fieldbus protocols is the so-called Profibus protocol. Fieldbusses, for example, the so-called Profibus DP fieldbus, are used especially in explosion-endangered environments. The electronics of the field devices must then be designed corresponding to the process environment. In such case, usual is an isolation in the primary and secondary circuits relative to the energy supply, as well as a limiting of the available energy. Galvanic isolation occurs in such case, most often, via optical isolators or via transformers. Since, however, the Profibus protocol can transmit frequencies up to 12 MBaud, relatively expensive optical isolators are required, respectively such optical isolator's do not meet the requirements of one of the ignition protection types.

It is, consequently, an object of the present invention to provide cost effective signal transfer with good efficiency as well as sufficiently high achievable data rate.

The object is achieved according to the invention by a circuit for signal transfer and galvanic isolation as well as by a field device of process automation technology as well as also by a method for signal transfer and galvanic isolation.

As regards the circuit, the object is achieved by a circuit for signal transfer and galvanic isolation between first and second digital data processing units.

In such case, a first signal path is provided between the first and the second signal processing units, wherein the first signal path has a first section, which includes positive and negative signal lines. The first signal path with its positive and negative signal lines serves, in such case, for transfer of a differential signal between the first and second signal processing units. The differential signal is composed, in such case, of a positive signal, which is transmitted via the positive signal line and a negative signal, which is equal, however, of opposite polarity, to the positive signal.

Furthermore, at least one capacitor is provided in the positive signal line and at least one capacitor in the negative signal line. The capacitors in the positive, respectively negative, signal lines serve, in such case, for galvanic isolation between the first and second signal processing units. These capacitors are, in each case, embodied according to the specifications of the ignition protection type, intrinsic safety. The creepage distance in air, respectively the creepage distance under a protective layer, of the utilized capacitors is, in such case, selected corresponding to the ignition protection type, intrinsic safety. The corresponding values for the creepage distance in air, respectively the creepage distance under a protective layer, are set forth in the standard EN60079-11 as a function of voltage. The required relatively large form of construction of the capacitors makes possible the maintaining of the creepage distances, respectively the air paths between the galvanically separated electrical current circuits, which comprise, for example, the first and second signal processing units.

In a form of embodiment of the proposed circuit, a second section and a third section are provided in the first signal path between the first and second signal processing units. The second and third sections serve, in such case, in each case, to transmit a non-differential signal between the first and second signal processing units. The first section is arranged between the second and the third sections. Data transfer between the first and second signal processing units occurs, in such case, sectionally by means of a non-differential signal and a differential signal. The digital, preferably binary, data are, thus, transmitted in the form of a non-differential signal via the second section. Then the data are transferred via the first section as a differential signal and, finally, transmitted via the third section again as a non-differential signal are.

In a form of embodiment of the proposed circuit, the second section serves to transmit a non-differential signal output from the first signal processing unit to a transferring unit. The transferring unit serves to convert the non-differential signal transmitted from the first signal processing unit into the differential signal and to transfer such via the first section. This transferring unit is, thus, arranged between the second and the first sections of the first signal path.

In an additional form of embodiment of the proposed circuit, a receiving unit is provided, which serves to receive the differential signal transferred via the first section by the transferring unit and to convert such into an a non-differential signal. The non-differential signal is then transmitted via the third section to the second signal processing unit. This receiving unit is thus arranged between the first section and the third section of the first signal path.

In an additional form of embodiment of the proposed circuit, a second signal path is provided between the second and the first signal processing units. The second signal path has a fourth section, which serves, to transfer a differential signal between the second and the first signal processing units. The fourth section of the second signal path includes positive and negative signal lines, which serve for transfer of the differential signal. In such case, at least one capacitor is provided in the positive signal line and at least one capacitor in the negative signal line, wherein the capacitors serve for galvanic isolation between the second signal processing unit and the first signal processing unit. The capacitors are, in each case, embodied according to the specifications of the ignition protection type, intrinsic safety. The first signal path serves thus for transfer of signals from the first signal processing unit to the second signal processing unit while the second signal path serves for transfer of data from the second signal processing unit to the first signal processing unit.

In an additional form of embodiment of the proposed circuit, a fifth and a sixth section are provided in the second signal path between the second and the first signal processing units. The fifth and the sixth sections serve, in each case, to transmit a non-differential signal between the second and the first signal processing units, wherein the fourth section is arranged between the fifth and the sixth sections.

In an additional form of embodiment of the proposed circuit, the fifth section serves to transmit a non-differential signal output by the second signal processing unit to a transferring unit, while the transferring unit present in the second signal path serves to convert the non-differential signal output by the second signal processing unit into the differential signal and to transmit such via the fourth section. The transferring unit in the second signal path is thus arranged between the fourth and the fifth sections.

In an additional form of embodiment of the proposed circuit, a receiving unit is provided in the second signal path, which serves to receive the differential signal transferred by the transferring unit via the fourth section and to convert such into a non-differential signal. This non-differential signal is transmitted via the sixth section to the first signal processing unit. The receiving unit in the second signal path is thus arranged between the fourth section and the sixth section.

In an additional form of embodiment of the proposed circuit, the first signal processing unit is an operating electronics, especially a microprocessor, of a field device.

In an additional form of embodiment of the proposed circuit, the second signal processing unit is a communication unit for communication, i.e. data transfer, via a fieldbus. Such a circuit enables transmission in explosion-endangered areas in an industrial plant with high data rates, especially in the range between 9.6 KBaud to 12 Baud, i.e. up to and beyond 20 Mbit (Mbit stands for megabit). Additionally, it is not necessary in the case of the data transfer via the fieldbus that data reduction occur in the field device for the purpose of galvanic isolation. In the case of the forms of embodiment of intrinsically safe circuits for data transfer known from the state of the art, it was due to the utilized optical components often not possible, in these explosion-endangered areas, to achieve such high data rates in the data transfer.

In an additional form of embodiment of the proposed circuit, the differential signal is a so-called LVDS (low voltage differential signaling) signal.

In an additional form of embodiment of the proposed circuit, the first signal path serves for sending signals from the first to the second signal processing unit.

In an additional form of embodiment of the proposed circuit, the second signal path serves for sending signals from the second to the first signal processing unit. Data can, thus, be transmitted via the first signal path from the first to the second signal processing unit. Furthermore, data can be transmitted via the second signal path from the second signal processing unit to the first signal processing unit. Thus, data, which are being exchanged between the first and second signal processing units, are present in the different sections of the first and second signal paths, first of all, in non-differential shape, are then converted into a differential signal and, finally, back into a non-differential signal. The section, in which the data are transferred in the form of the differential signal, serves, in such case, both for galvanic isolation as well as also for fulfilling the requirements for intrinsic safety, especially for the ignition protection type, intrinsic safety.

In an additional form of embodiment of the proposed circuit, a third signal path is provided between the first and second signal processing units. The third signal path serves, in such case, for transferring a signal that serves far selection of the first, respectively the second, signal path for signal transfer between the first and second signal processing units. By this third signal path and the signal transferred thereby, thus, the direction of the data transfer can be selected.

As regards the field device, the object is achieved by a field device of process automation technology having a circuit as claimed in one of the preceding claims. As already mentioned, the first signal processing unit can then be an operating electronics, respectively a part of the operating electronics, of the field device and serving for performing the functions of the field device and the second signal processing unit a communication unit serving for placing signals output by the operating electronics onto a fieldbus line.

As regards the method, the object is achieved by a method for signal transfer and galvanic isolation between first and second signal processing units, wherein a first signal path is provided between the first and second signal processing units, wherein the first signal path has a first section, which has positive and negative signal lines, wherein at least one capacitor is provided in the positive signal line and at least one capacitor is provided in the negative signal line. The capacitors serve for galvanic isolation between the first signal processing unit and the second signal processing unit, respectively for galvanic isolation between the first and second signal processing units used. Additionally, the capacitors are embodied according to the specifications of the ignition protection type, intrinsic safety and serve to transmit a differential signal from the first and to the second signal processing unit via the first signal path, especially in the first section of the signal path.

The invention will now be explained in greater detail based on the appended drawing, the figures of which show as follows:

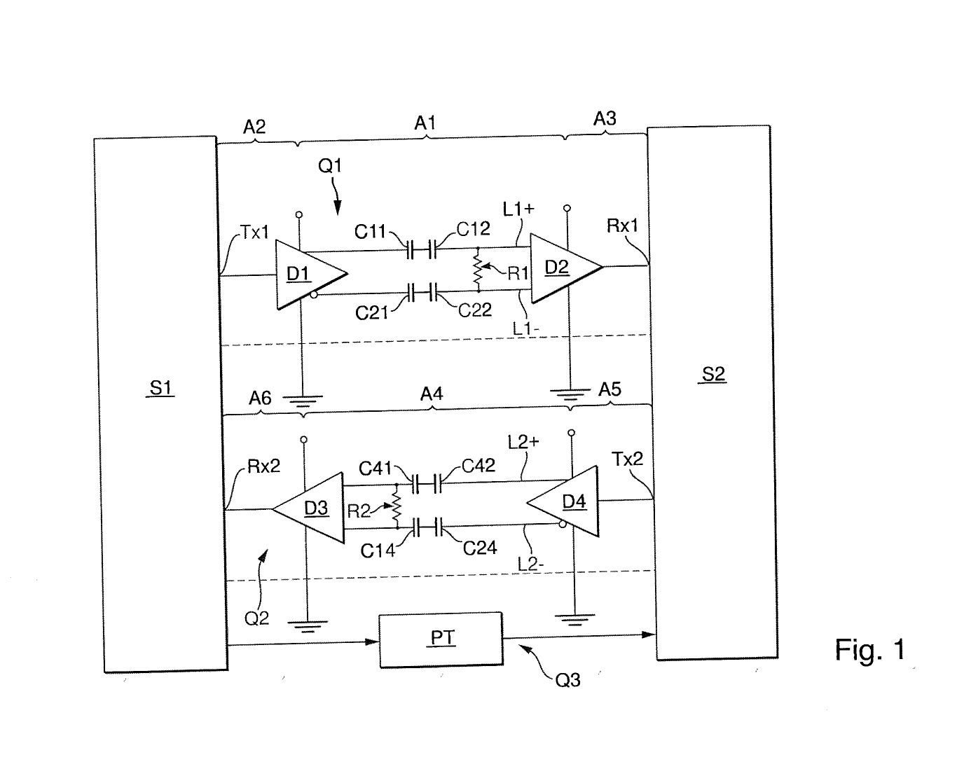

FIG. 1 a diagram of a form of embodiment of the proposed circuit,

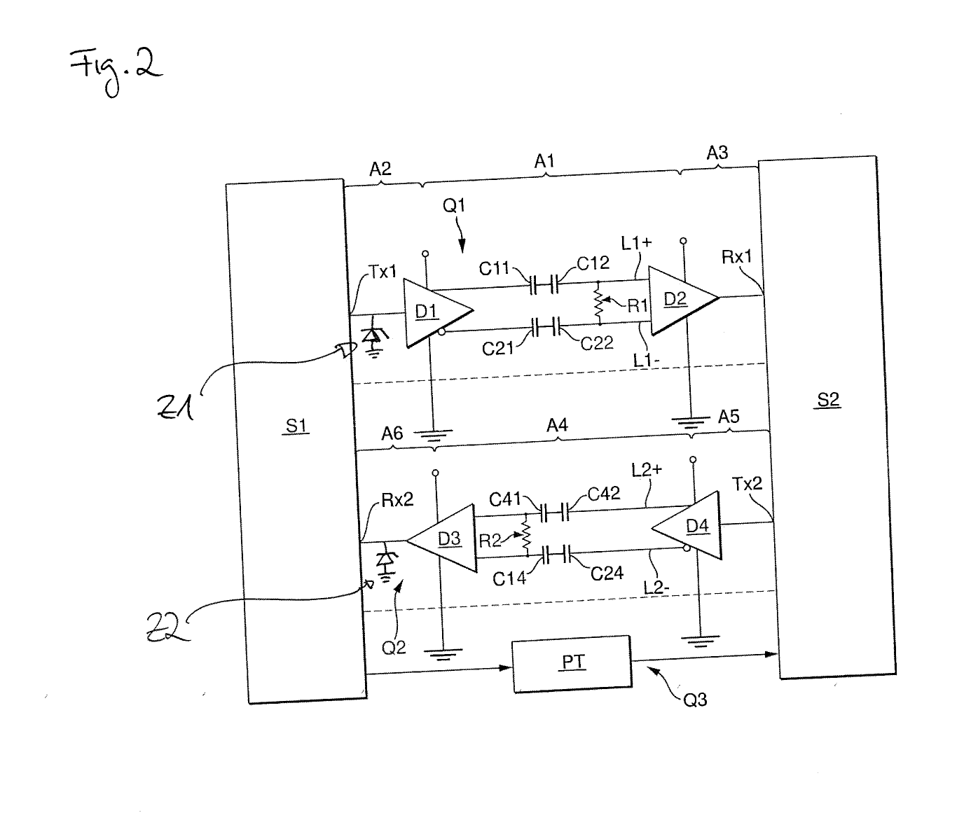

FIG. 2 a diagram of an additional form of embodiment of the proposed circuit.

FIG. 1 shows the diagram of a form of embodiment of the proposed circuit. First and second signal processing units S1, S2 are, in such case, connected with one another via a first signal path Q1 and a second signal path Q2 as well as a third signal path Q3. The first and second signal paths Q1, respectively Q2, serve, in such case, for data transfer between the first and second signal processing units. The data can be, for example, field device data such as, for example, a measured value or one or more parameters of the field device. The third signal path Q3 serves for selection of the first or the second signal path Q1, respectively Q2. Transmitted via the third signal path Q3 is a corresponding switching signal, for example, across a galvanic barrier PT. Galvanic barrier PT can be a so-called print transformer. For data transfer of data from the first signal processing unit S1 to the second signal processing unit S2, corresponding signals are transmitted from the first signal processing unit S1 via a signal output Tx1 and via a second section of the first signal path to a transferring unit D1. Transferring unit D1 converts the non-differential signal output by the first signal processing unit into a differential signal. The differential signal is then transferred via a first section A1 of the first signal path Q1 to a receiving unit D2. The first section A1 in the first signal path Q1 includes according to the form of embodiment in FIG. 1 a positive signal line L1+ and a negative signal line L1−, which serve for transfer of the differential signal. The positive signal component of the differential signal is transferred via the positive signal line L1+ and the negative signal component of the differential signal is transferred via the negative signal line L1−. Integrated in the positive as well as also the negative signal lines L1+, L1− are, furthermore, capacitors C11, C12, C21, C22 for galvanic isolation. Thus, the positive signal line has two series connected capacitors C11 and C12 and the negative signal line L1 has likewise two series connected capacitors C12 and C22. The capacitors are embodied, in such case, according to the requirements of the ignition protection type, intrinsic safety. The differential signal received by the receiving unit via the first section A1 is converted back into a non-differential signal and transmitted to a receiving channel Rx1 of the second signal processing unit S2 via a third section A3 of the first signal path Q1.

Serving for data transfer from the second signal processing unit S2 to the first signal processing unit S1 is the second signal path Q2. For data transfer, a non-differential signal is transmitted on the signal output Tx2 of the second signal processing unit S2 via a fifth section A5 of the second signal path Q2 to a transferring unit D4. Transferring unit D4 serves for converting the non-differential signal into a differential signal, which is transferred via a fourth section A4 of the second signal path Q2 to a receiving unit D3. Receiving unit D3 converts the differential signal, in turn, back into a non-differential signal and transmits such via a sixth section A6 of the second signal path Q2 to a receiving channel Rx2 of the first signal processing unit S1. Corresponding to the first signal path Q1, especially the first section of the first signal path, and connected in series with one another in the fourth section of the second signal path in the positive signal line L2+ and in the negative signal line L2 of the fourth section A4 of the second signal path Q2 are the capacitors C41, respectively C42, and the capacitors C14, respectively C24. As in the first section A1 of the first signal path Q1, these capacitors serve for galvanic isolation. Furthermore, the capacitors C41, C42, C14, C24 are likewise designed according to the ignition protection type, intrinsic safety.

The proposed circuit can be applied preferably in a field device of automation technology. Thus, for example, the second signal processing unit S2 can be a communication unit of a field device, which is connected to a fieldbus. Especially preferably, the communication unit is a so-called RS485 transceiver. In this embodiment, the third signal path Q3 can be a signal path for transferring a switching signal for switching the transceiver between sending and receiving.

The circuit shown in FIG. 1 is composed, in such case, essentially of four low voltage differential signaling chips in the form of the transferring-receiving units D1, D2, D3 and D4. The transferring unit D1, respectively the transferring unit D4 in the first, respectively in the second, signal paths Q1, Q2 can, for example, transfer a so-called TTL signal with a voltage level of 0, respectively 3.3V, which TTL signal is transferred by means of the four capacitors C11, C12, C21 respectively C22 to the receiving units D2, respectively D3. The applied capacitors enable that the proposed circuit can be used in an explosion-endangered area.

Instead of the series connected capacitors in the positive, respectively negative, signal lines L1+, L1−, L2+, L2−, also only single capacitors embodied according to the ignition protection type, intrinsic safety can be used for galvanic isolation between the first and second signal processing units. The receiving circuits D2 respectively D3, convert the differential signal back into a TTL signal. The resistances R1, R2 in the first section of the first signal path Q1, respectively the fourth section A4 of the second signal path Q2, serve for signal conditioning and adapting the bandwidth in the case of the LVDS chips used for signal transfer. Correspondingly, higher data rates can be achieved by an adapting of these resistances R1, R2. The proposed circuit enables, without derating, data transfer from the first to the second signal processing unit S1, S2, respectively from the second to the first signal processing unit S2, S1 and use of the same data transfer rate in the case of the communication via the fieldbus (not shown).

FIG. 2 shows a form of embodiment of the proposed circuit, which essentially agrees with that of FIG. 1. In the section A2, respectively A6, there is, however, supplementally provided a junction, which is connected via a diode Z1, Z2, preferably Zener diodes, with ground for the purpose of voltage limiting. Instead of a diode, other means can be provided for voltage limiting. These means for voltage limiting are arranged in a section of the signal path in which the non-differential signal is present. The means for voltage limiting are, thus, according to FIG. 2, arranged between the first signal processing system S1 and the signal processing units D1, respectively D3, respectively between the first signal processing system S1 and a corresponding junction provided in the section A2, respectively A6.

Together with the capacitors C11 . . . , C24, thus, by way of the means for voltage limiting, for example, the Zener diodes Z1, Z2, an energy limiting, respectively power limiting, of the electrical energy, respectively power, transmitted via the signal lines can occur. Especially, thus, an ATEX, respectively Ex I, energy, respectively power, limiting can be achieved, so that the circuit fulfills the requirements of the ignition protection type, intrinsic safety.

Especially, it can be provided that the proposed circuit, respectively a field device with such a circuit, has no additional means for energy, respectively power, limiting, but, instead, the requirements of the ignition protection type, intrinsic safety are achieved exclusively by the means for voltage limiting, preferably the Zener diodes Z1, Z2, and the capacitors C11 . . . , C24.

In the case of malfunction, the means for voltage limiting, here the Zener diodes Z1, Z2, thus, serve for power limiting. For example, the Zener diodes can have a Zener voltage of 3.6 volt, in order in the case of malfunction, to deflect an overcurrent to ground, and, thus, achieve a durable protection of the downstream components, such as, for example, transferring/receiving units D1, D2.

### LIST OF REFERENCE CHARACTERS

S1 first signal processing unit
S2 second signal processing unit
Q1 first signal path
Q2 second signal path
Q3 third signal path
A1 first section
A2 second section
A3 third section
A4 fourth section
A5 fifth section
A6 sixth section
Tx1 first signal output
Tx2 second signal output
Rx1 first signal input
Rx2 second signal input
D1 transferring unit
D2 receiving unit
D3 receiving unit
D4 transferring unit
C11 capacitor
C12 capacitor
C21 capacitor
C22 capacitor
C41 capacitor
C42 capacitor
C14 capacitor
C24 capacitor
PT galvanic barrier
L1+ positive signal line
L1− negative signal line
L2+ positive signal line
L2− negative signal line
R1 first resistor
R2 second resistor

1-15. (canceled)

16. A circuit for signal transfer and galvanic isolation, comprising:
first and second digital signal processing units;
a first signal path provided between said first and said second signal processing units, said first signal path has a first section, which includes positive and negative signal lines and serves for transfer of a differential signal between said first and second signal processing units; and
at least one capacitor in said positive signal line and at least one capacitor in said negative signal line, wherein:
said capacitors serve for galvanic isolation between said first signal processing unit and said second signal processing unit; and
said capacitors are, in each case, embodied according to the specifications of the ignition protection type, intrinsic safety.

17. The circuit as claimed in claim 16, further comprising:
a second section and a third section provided in said first signal path between said first and second signal processing units and serve, in each case, to transmit a non-differential signal between said first and second signal processing units, wherein:
said first section is arranged between said second and the third section.

18. The circuit as claimed in claim 16, further comprising:
a transferring unit, wherein:
said second section serves to transmit a non-differential signal output of said first signal processing unit to said transferring unit, which serves to convert the non-differential signal transmitted from said first signal processing unit into the differential signal and transfer such via said first section.

19. The circuit as claimed in claim 16, further comprising:
a receiving unit, which serves to receive the differential signal transferred by said transferring unit via said first section and to convert such into a non-differential signal and to transmit such via said third section to said second signal processing unit.

20. The circuit as claimed in claim 16, further comprising:
a second signal path is provided between said second and said first signal processing units, wherein:
said second signal path has a fourth section, which serves to transfer a differential signal between said second and said first signal processing units;
said fourth section of said second signal path includes positive and negative signal lines;
at least one capacitor is provided in said positive signal line and at least one capacitor in said negative signal line;
said capacitors serve for galvanic isolation between said second signal processing unit and said first signal processing unit; and
said capacitors are, in each case, embodied according to the specifications of the ignition protection type, intrinsic safety.

21. The circuit as claimed in claim 18, further comprising:
a fifth section and a sixth section in said second signal path between said second and said first signal processing units, and serve, in each case, to transmit a non-differential signal between said second and said first signal processing units; and
said fourth section is arranged between said fifth and said sixth sections.

22. The circuit as claimed in claim 21, wherein:
said fifth section serves to transmit a non-differential signal output by said second signal processing unit to said transferring unit, which serves to convert the non-differential signal transmitted by said second signal processing unit into the differential signal and to transmit such via said fourth section.

23. The circuit as claimed in claim 18, further comprising:
a receiving unit, which serves to receive the differential signal transferred by said transferring unit via said fourth section and to convert such into a non-differential signal and to transmit such via said sixth section to said first signal processing unit.

24. The circuit as claimed in claim 16, wherein:
said first signal processing unit is an operating electronics, especially a microprocessor, of a field device.

25. The circuit as claimed in claim 16, wherein;
said second signal processing unit is a communication unit for communication, i.e. data transfer, via a fieldbus.

26. The circuit as claimed in claim 16, wherein:
the differential signal is an LVDS signal.

27. The circuit as claimed in claim 16, wherein:
said first signal path serves for sending signals from said first to said second signal processing unit, and
said second signal path serves for sending signals from said second to said first signal processing unit.

28. The circuit as claimed in claim 16, further comprising:
a third signal path between said first and second signal processing units, wherein:
said third signal path serves for transferring a signal, which serves for selection of said first, respectively said second, signal path for signal transfer between said first and said second signal processing units.

29. A field device of process automation technology having a circuit comprising:
first and second digital signal processing units; a first signal path provided between said first and said second signal processing units, said first signal path has a first section, which includes positive and negative signal lines and serves for transfer of a differential signal between said first and second signal processing units; and at least one capacitor in said positive signal line and at least one capacitor in said negative signal line, wherein: said capacitors serve for galvanic isolation between said first signal processing unit and said second signal processing unit; and said capacitors are, in each case, embodied according to the specifications of the ignition protection type, intrinsic safety.

30. A method for signal transfer and galvanic isolation between first and second signal processing units, comprising the steps of:
a first signal path is provided between the first and second signal processing units;
the first signal path has a first section, which includes positive and negative signal lines;
at least one capacitor is provided in the positive signal line and at least one capacitor in the negative signal line;
the capacitors are used for galvanic isolation between the first signal processing unit and the second signal processing unit;
the capacitors are embodied, in each case, according to the specifications of the ignition protection type, intrinsic safety;
a differential signal is transferred between the first and second signal processing units via the first section of the first signal path.
